(19) United States
(12) Patent Application Publication
(10) Pub. No.: US 2020/0301049 A1
(43) Pub. Date: Sep. 24, 2020

(54) OPTICAL DEFLECTION ELEMENT, METHOD FOR MANUFACTURING OPTICAL DEFLECTION ELEMENT, AND SYSTEM INCLUDING OPTICAL DEFLECTION ELEMENT

(71) Applicant: KAZUTAKA NIIGATA, OSAKA (JP)

(72) Inventor: KAZUTAKA NIIGATA, OSAKA (JP)

(73) Assignee: Ricoh Company, Ltd., Tokyo (JP)

(21) Appl. No.: 16/800,127

(22) Filed: Feb. 25, 2020

(30) Foreign Application Priority Data
Mar. 18, 2019 (JP) 2019-050485

(51) Int. Cl. G02B 5/08; G02B 1/14; G02B 5/26; C23C 16/455; G02B 1/115; C23C 16/34; C23C 16/40; C23C 28/00

(52) U.S. Cl. CPC G02B 5/0833; G02B 1/14; G02B 5/26; C23C 16/45525; C23C 28/321; C23C 16/345; C23C 16/402; C23C 16/403; G02B 1/115

(57) ABSTRACT

An optical deflection element includes: a reflective surface; and a movable part configured to rotate the reflective surface so as to deflect light incident on the reflective surface. The movable part includes: a metal film; a high reflective layer formed on an upper surface of the metal film; and a protective film continuously covering an upper surface and a side surface of the high reflective layer and a side surface of the metal film.

### CROSS-REFERENCE TO RELATED APPLICATIONS

This patent application is based on and claims priority pursuant to 35 U.S.C. § 119(a) to Japanese Patent Application No. 2019-050485, filed on Mar. 18, 2019, in the Japan Patent Office, the entire disclosure of which is hereby incorporated by reference herein.

### BACKGROUND

### Technical Field

The present invention relates to an optical deflection element, a method for manufacturing the optical deflection element, and a system including the optical deflection element.

### Description of the Related Art

In recent years, microelectromechanical systems (MEMS) devices using a piezoelectric film as an actuator have been increasingly used. For example, scanner devices including a reflective surface for the purpose of optical scanning have been developed.

Examples of the MEMS device include an optical deflection element that includes a torsion bar including a metal alloy, an oscillation body bonded to the torsion bar, a magnet bonded to the oscillation body, and a member having a water barrier property to protect the bonding area between the torsion bar and the oscillation body with a bonding adhesive from water. In the optical deflection element, the oscillation body includes a first oscillation body and a second oscillation body between which part of the torsion bar is sandwiched. The member having a water barrier property is provided to cover the surface and its periphery of the bonding area between the torsion bar and the oscillation body with the bonding adhesive. The member having a water barrier property protects a reflective surface of the oscillation body.

Unfortunately, the above optical deflection element has a disadvantage such as the deterioration of the optical characteristics due to an increase in the thickness of the member that protects the reflective surface of the oscillation body.

### SUMMARY

Example embodiments include an optical deflection element includes: a reflective surface; and a movable part configured to rotate the reflective surface so as to deflect light incident on the reflective surface. The movable part includes: a metal film; a high reflective layer formed on an upper surface of the metal film; and a protective film continuously covering an upper surface and a side surface of the high reflective layer and a side surface of the metal film.

### BRIEF DESCRIPTION OF THE SEVERAL VIEWS OF THE DRAWINGS

A more complete appreciation of the disclosure and many of the attendant advantages and features thereof may be readily obtained and understood from the following detailed description referring to the accompanying drawings, wherein:

FIG. 1 is a schematic view illustrating an example of an optical scanning system according to an embodiment of the present invention;

FIG. 2 is a diagram illustrating an example of the hardware configuration of the optical scanning system according to the embodiment;

FIG. 3 is a block diagram illustrating an example of the functional configuration of a control device according to the embodiment;

FIG. 4 is a flowchart illustrating an example of a process performed by the optical scanning system according to the embodiment;

FIG. 5 is a schematic view illustrating an example of an automobile including a head-up display device according to the embodiment;

FIG. 6 is a schematic view illustrating an example of the head-up display device according to the embodiment;

FIG. 7 is a schematic view illustrating an example of an image forming apparatus including an optical writing device according to the embodiment;

FIG. 8 is a schematic view illustrating an example of the optical writing device according to the embodiment;

FIG. 9 is a schematic view illustrating an automobile including a laser imaging detection and ranging (LiDAR) device according to the embodiment;

FIG. 10 is a schematic view illustrating an example of the LiDAR device according to the embodiment;

FIG. 11 is a schematic view illustrating an example of the configuration of a laser headlamp according to the embodiment;

FIG. 12 is a perspective view schematically illustrating an example of the configuration of a head mount display according to the embodiment;

FIG. 13 is a partial view illustrating an example of the configuration of the head mount display according to the embodiment;

FIG. 14 is a schematic view illustrating an example of a packaged movable device according to the embodiment;

FIG. 15 is a plan view illustrating the movable device according to a first embodiment of the present invention;

FIG. 16 is a cross-sectional view taken through the line A-A in FIG. 15;

FIG. 17 is a cross-sectional view taken through the line B-B in FIG. 15;

FIG. 18 is a cross-sectional view illustrating an example of a mirror unit according to a comparative example;

FIG. 19 is a cross-sectional view illustrating an example of the mirror unit according to the first embodiment;

FIG. 20 is a graph illustrating a difference in the reflectance between mirror units due to the presence or absence of a protective film according to the embodiment;

FIGS. 21A and 21B are schematic views illustrating the cross-section of the protective film according to the embodiment;

FIG. 22 is a cross-sectional view illustrating an example of a mirror unit according to a second embodiment of the present invention; and

FIG. 23 is a graph illustrating the difference in the reflectance of the mirror unit depending on the number of layers in the protective film according to the embodiment.

The accompanying drawings are intended to depict embodiments of the present invention and should not be interpreted to limit the scope thereof. The accompanying drawings are not to be considered as drawn to scale unless explicitly noted.

### DETAILED DESCRIPTION

The terminology used herein is for the purpose of describing particular embodiments only and is not intended to be limiting of the present invention. As used herein, the singular forms “a”, “an” and “the” are intended to include the plural forms as well, unless the context clearly indicates otherwise.

In describing embodiments illustrated in the drawings, specific terminology is employed for the sake of clarity. However, the disclosure of this specification is not intended to be limited to the specific terminology so selected and it is to be understood that each specific element includes all technical equivalents that have a similar function, operate in a similar manner, and achieve a similar result.

Embodiments of the present invention are described below in detail.

### Optical Scanning System

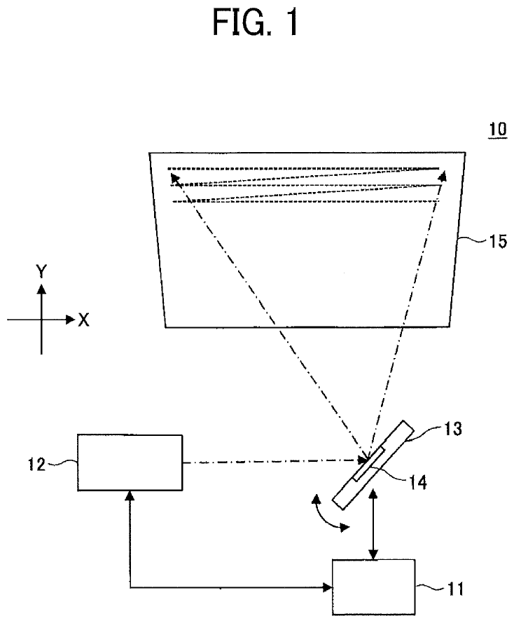

Referring to FIGS. 1 to 4, an optical scanning system 10 to which a movable device 13 according to the present embodiment is applied is first described in detail.

FIG. 1 is a schematic view illustrating an example of the optical scanning system 10. As illustrated in FIG. 1, the optical scanning system 10 includes a control device 11, a light source device 12, and the movable device 13 including a reflective surface 14.

In the optical scanning system 10, the reflective surface 14 included in the movable device 13 deflects the light emitted from the light source device 12 under the control of the control device 11 so as to optically scan a scan surface 15.

The control device 11 includes an electronic circuitry unit including, for example, a central processing unit (CPU) or a field-programmable gate array (FPGA). The movable device 13 includes, for example, an MEMS device that includes the reflective surface 14 and allows the reflective surface 14 to move. The light source device 12 includes, for example, a laser device that emits a laser. The scan surface 15 includes, for example, a screen.

The control device 11 generates a control command for the light source device 12 and the movable device 13 based on the acquired optical scanning information and outputs a drive signal to the light source device 12 and the movable device 13 based on the control command.

The light source device 12 emits light based on the input drive signal. The movable device 13 moves the reflective surface 14 based on the input drive signal in at least any of one axial direction and two axial directions.

Thus, for example, due to the control by the control device 11 based on image information, which is an example of the optical scanning information, the reflective surface 14 of the movable device 13 is moved back and forth in two axial directions within a predetermined range, and the light emitted from the light source device 12 and entering the reflective surface 14 is deflected around a certain axis for optical scanning, whereby any image may be projected onto the scan surface 15. The details of the movable device 13 and the details of the control by the control device 11 according to the present embodiment are given later.

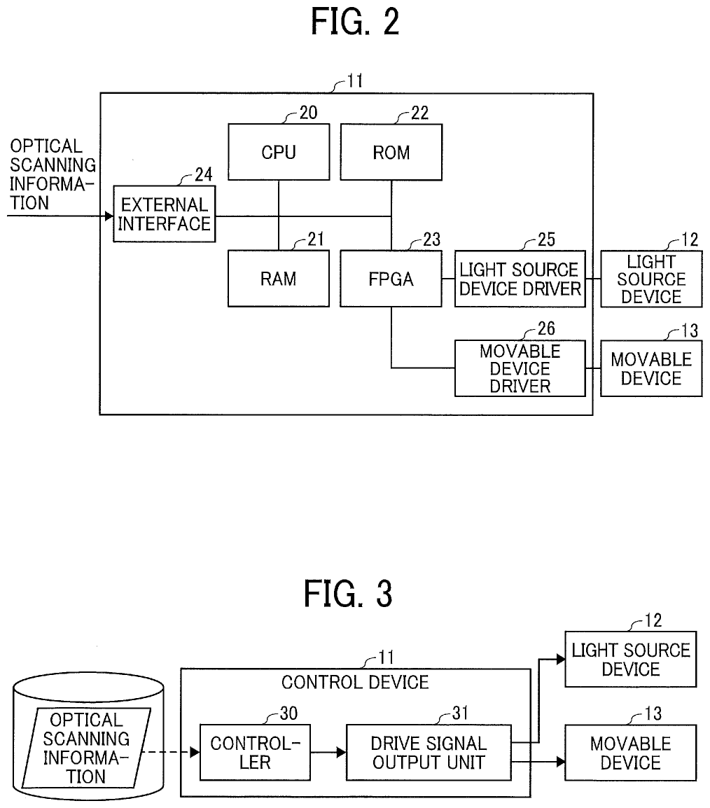

Referring to FIG. 2, an example of the hardware configuration of the optical scanning system 10 is described below. FIG. 2 is a diagram illustrating an example of the hardware configuration of the optical scanning system 10. As illustrated in FIG. 2, the optical scanning system 10 includes the control device 11, the light source device 12, and the movable device 13. The control device 11, the light source device 12, and the movable device 13 are electrically connected to one another. The control device 11 includes a CPU 20, a random access memory (RAM) 21, a read only memory (ROM) 22, an FPGA 23, an external interface (I/F) 24, a light source device driver 25, and a movable device driver 26.

The CPU 20 is an arithmetic device that loads a program or data from a storage device, such as the ROM 22, onto the RAM 21 and executes processing so as to perform the overall control on the control device 11 and perform a function of the control device 11.

The RAM 21 is a volatile storage device that temporarily stores programs and data.

The ROM 22 is a non-volatile storage device that may retain programs and data even when the power is off. The ROM 22 stores processing programs and data that are executed by the CPU 20 to control each function of the optical scanning system 10.

The FPGA 23 is a circuitry that outputs a control signal appropriate for the light source device driver 25 and the movable device driver 26 in accordance with processing of the CPU 20.

The external I/F 24 is an interface with, for example, an external device or a network. Examples of the external device include a higher-level device such as a personal computer (PC) and a storage device such as a universal serial bus (USB) memory, a secure digital (SD) Card, a compact disc (CD), a digital versatile disk (DVD), a hard disk drive (HDD), or a solid state drive (SSD). Examples of the network include a controller area network (CAN) for automobiles, a local area network (LAN), or the Internet. The external I/F 24 may be configured to enable the connection or communication with an external device. The external I/F 24 may be provided for each external device.

The light source device driver 25 is an electric circuitry that outputs a drive signal such as a drive voltage to the light source device 12 in accordance with an input control signal.

The movable device driver 26 is an electric circuitry that outputs a drive signal such as a drive voltage to the movable device 13 in accordance with an input control signal.

In the control device 11, the CPU 20 acquires optical scanning information from an external device or a network via the external I/F 24. As long as the CPU 20 is configured to acquire optical scanning information, the optical scanning information may be stored in the ROM 22 or the FPGA 23 in the control device 11, or the optical scanning information may be stored in a storage device, such as an SSD, which is newly provided in the control device 11.

The optical scanning information is the information indicating how the scan surface 15 is optically scanned. For example, the optical scanning information is image data when an image is displayed due to optical scanning. Furthermore, for example, the optical scanning information is the writing data indicating a writing order or a writing location when optical writing is executed due to optical scanning. Moreover, for example, the optical scanning information is the emission data indicating the timing and the emission range for emitting light for object recognition when the object recognition is executed due to optical scanning.

The control device 11 may provide the functional configuration described below by using the hardware configuration illustrated in FIG. 2 in accordance with a command from the CPU 20.

Referring to FIG. 3, an example of the functional configuration of the control device 11 in the optical scanning system 10 is described below. FIG. 3 is a block diagram illustrating an example of the functional configuration of the control device 11 in the optical scanning system 10.

As illustrated in FIG. 3, the control device 11 includes a controller 30 and a drive signal output unit 31 as functions.

The controller 30 is implemented by using, for example, the CPU 20 or the FPGA 23. The controller 30 acquires optical scanning information from an external device, converts the optical scanning information into a control signal, and outputs the control signal to the drive signal output unit 31. For example, the controller 30 acquires image data as the optical scanning information from an external device, or the like, generates a control signal from the image data through predetermined processing, and outputs the control signal to the drive signal output unit 31.

The drive signal output unit 31 is implemented by using, for example, the light source device driver 25 or the movable device driver 26. The drive signal output unit 31 outputs a drive signal to the light source device 12 or the movable device 13 based on an input control signal. The drive signal is a signal for controlling the driving of the light source device 12 or the movable device 13. For example, for the light source device 12, the drive signal is the drive voltage for controlling the emission timing and the emission intensity of the light source. For example, for the movable device 13, the drive signal is the drive voltage for controlling the moving timing and the movable range of the reflective surface 14 included in the movable device 13.

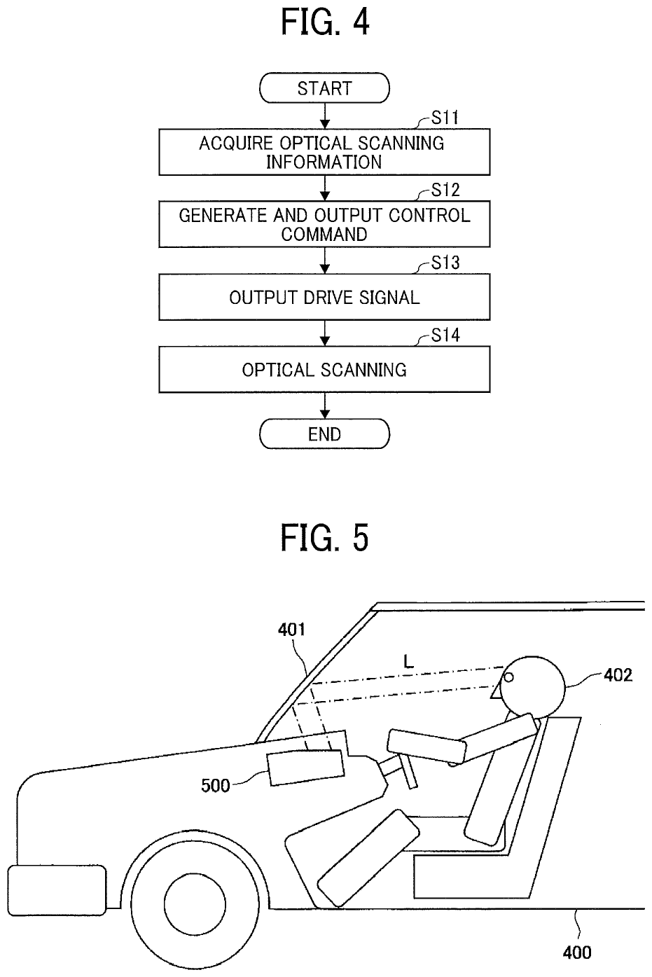

Referring to FIG. 4, the process performed by the optical scanning system 10 to optically scan the scan surface 15 is described below. FIG. 4 is a flowchart illustrating an example of the process performed by the optical scanning system 10.

In step S11, the controller 30 acquires optical scanning information from an external device, etc.

In step S12, the controller 30 generates a control signal, which is a control command, from the acquired optical scanning information and outputs the control signal to the drive signal output unit 31.

In step S13, the drive signal output unit 31 outputs a drive signal to the light source device 12 and the movable device 13 based on the input control signal.

In step S14, the light source device 12 emits light based on the input drive signal. The movable device 13 moves the reflective surface 14 based on the input drive signal. Driving of the light source device 12 and the movable device 13 allows the light to be deflected in any direction for the optical scanning.

In the optical scanning system 10, the device for controlling the light source device 12 and the device for controlling the movable device 13 are incorporated into the single control device 11, that is to say, the single control device 11 has the function to control the light source device 12 and the function to control the movable device 13; however, a control device that controls the light source device 12 and a control device that controls the movable device 13 may be provided separately.

In the optical scanning system 10, the single control device 11 has the function of the controller 30 for the light source device 12 and the movable device 13 and the function of the drive signal output unit 31; however, these functions may be provided separately. For example, a drive signal output device including the drive signal output unit 31 may be provided separately from the control device 11 including the controller 30. In the optical scanning system 10, the movable device 13 including the reflective surface 14 and the control device 11 may constitute an optical deflection system that executes optical deflection.

### Image Projection Device

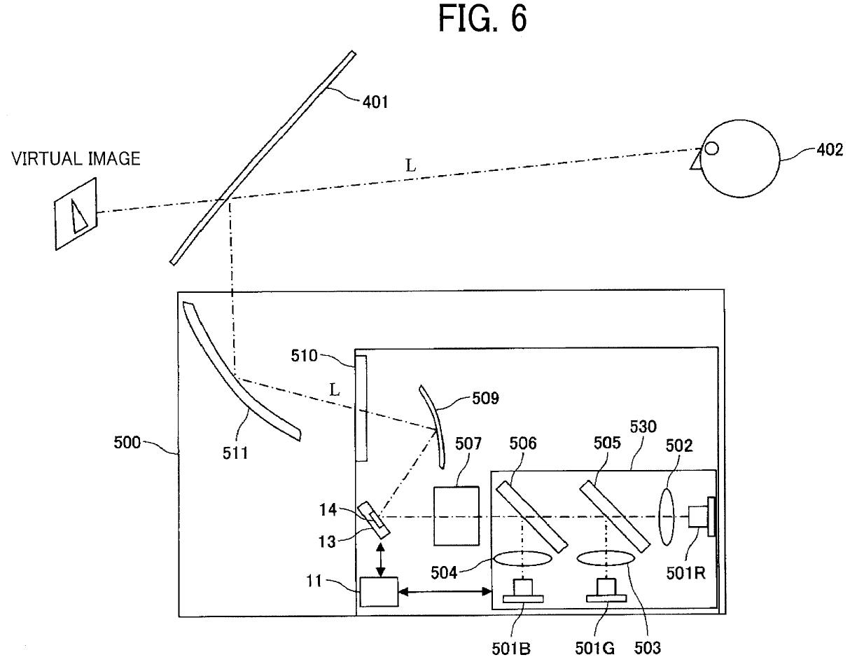

Referring to FIGS. 5 and 6, an image projection device using the movable device 13 according to the present embodiment is described below in detail.

FIG. 5 is a schematic view illustrating an example of an automobile 400 including a head-up display device 500, which is an example of the image projection device, according to an embodiment of the present invention. FIG. 6 is a schematic view illustrating an example of the head-up display device 500.

The image projection device projects an image due to optical scanning. The image projection device is, for example, a head-up display device.

As illustrated in FIG. 5, the head-up display device 500 is provided, for example, near the windshield (e.g., a front glass 401) of the automobile 400. A projection light L emitted from the head-up display device 500 is reflected by the front glass 401 and is headed to the viewer (a driver 402) who is a user. This allows the driver 402 to visually recognize the image, or the like, projected by the head-up display device 500 as a virtual image. A combiner may be provided on the inner wall surface of the windshield so that the projection light reflected by the combiner allows the user to visually recognize a virtual image.

As illustrated in FIG. 6, in the head-up display device 500, red, green, and blue laser light sources 501R, 501G, and 501B emit laser lights. The emitted laser lights pass through an incident optical system including collimator lenses 502, 503, and 504, which are provided for the respective laser light sources, two dichroic mirrors 505 and 506, and a light intensity adjuster 507. Then, the light is deflected by the movable device 13 including the reflective surface 14. The deflected laser light passes through a projection optical system including a free-form surface mirror 509, an intermediate screen 510, and a projection mirror 511 and is then projected onto a screen. In the head-up display device 500, the laser light sources 501R, 501G, and 501B, the collimator lenses 502, 503, and 504, and the dichroic mirrors 505 and 506 are housed as a light source unit 530 in an optical housing.

The head-up display device 500 projects the intermediate image displayed on the intermediate screen 510 onto the front glass 401 of the automobile 400 so as to allow the driver 402 to visually recognize the intermediate image as a virtual image.

The respective color laser lights emitted from the laser light sources 501R, 501G, and 501B are converted into substantially parallel lights by the collimator lenses 502, 503, and 504, respectively, and are then combined by the two dichroic mirrors 505 and 506. After the light intensity of the combined laser light is adjusted by the light intensity adjuster 507, the laser light is two-dimensionally swept by the movable device 13 including the reflective surface 14. The projection light L, which is two-dimensionally swept by the movable device 13, is reflected by the free-form surface mirror 509 to correct distortion and is then focused on the intermediate screen 510 so as to display an intermediate image. The intermediate screen 510 includes a microlens array in which microlenses are arranged in two dimensions. The intermediate screen 510 enlarges the projection light L incident on the intermediate screen 510 by microlenses.

The movable device 13 moves the reflective surface 14 back and forth in two axial directions to two-dimensionally sweep the projection light L entering the reflective surface 14. The driving control of the movable device 13 is executed in synchronization with the emission timing of the laser light sources 501R, 501G, and 501B.

The head-up display device 500, which is an example of the image projection device, has been described above. The image projection device may be any device that executes optical scanning by using the movable device 13 including the reflective surface 14 to project an image. The image projection device is also applicable as, for example, a projector that is placed on a desk, or the like, to project an image on a display screen, or a head mount display device that is provided in a mounting member attached to the viewer's head, etc., to project an image onto a reflection-transmission screen included in the mounting member or project an image onto an eyeball as a screen.

The image projection device may be mounted in not only a vehicle or a mounting member but also a movable body such as an aircraft, a ship, or a movable robot, or an immovable body such as a work robot that operates a driving target such as a manipulator without moving from the spot.

The head-up display device 500 is an example of a “head-up display” described in claims. The automobile 400 is an example of a “vehicle” described in claims.

### Optical Writing Device

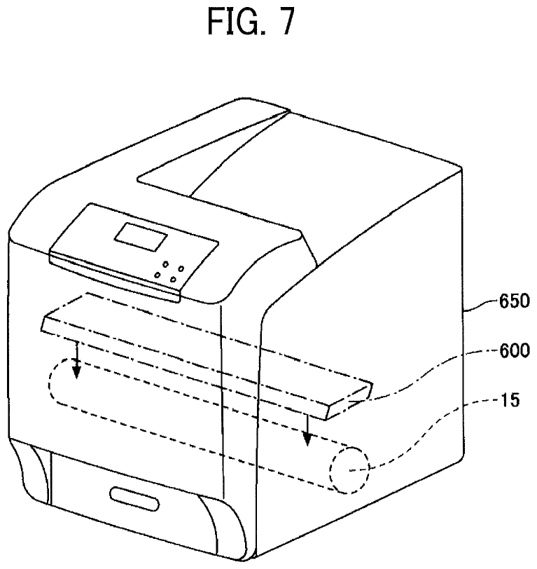

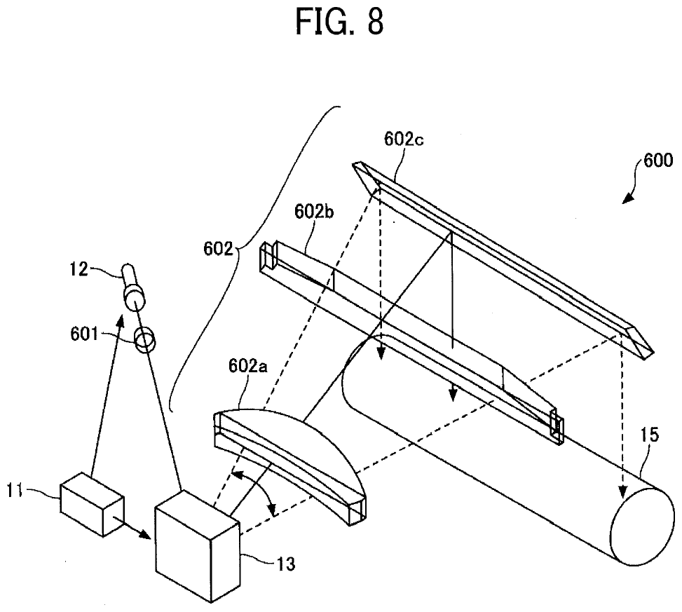

Referring to FIG. 7 and FIG. 8, an optical writing device using the movable device 13 according to the present embodiment is described below in detail.

FIG. 7 is a schematic view illustrating an example of an image forming apparatus including an optical writing device 600. FIG. 8 is a schematic view illustrating an example of the optical writing device 600.

As illustrated in FIG. 7, the optical writing device 600 is used as a component of the image forming apparatus, typically a laser printer 650 having a printer function using laser light. In the image forming apparatus, the optical writing device 600 optically scans a photosensitive drum, which is the scan surface 15, with one or more laser beams so as to execute optical writing on the photosensitive drum.

As illustrated in FIG. 8, in the optical writing device 600, the laser light from the light source device 12, such as a laser element, passes through an imaging optical system 601 such as a collimator lens and is then deflected by the movable device 13 including the reflective surface 14 in one axial direction or two axial directions. The laser light deflected by the movable device 13 passes through a scanning optical system 602 including a first lens 602a, a second lens 602b, and a reflection mirror unit 602c and is then emitted to the scan surface 15 (e.g., a photosensitive drum or photosensitive paper) for optical writing. The scanning optical system 602 focuses the optical beam in the form of a spot on the scan surface 15. The light source device 12 and the movable device 13 including the reflective surface 14 are driven based on the control of the control device 11.

As described above, the optical writing device 600 may be used as a component of an image forming apparatus having a printer function using laser light. With a different scanning optical system, optical scanning may be executed in two axial directions as well as in one axial direction so that the optical writing device 600 may be used as a component of an image forming apparatus such as a laser label apparatus that deflects laser light to a thermal medium for optical scanning and heats the thermal medium to execute printing.

The movable device 13 including the reflective surface 14 applied to the optical writing device 600 is advantageous in power saving of the optical writing device 600 because of low power consumption for driving as compared with a rotary polygon mirror using a polygon mirror, etc. Furthermore, the movable device 13 is advantageous in the improvement of quietness of the optical writing device 600 because of a small wind noise during the oscillation of the movable device 13 as compared with a rotary polygon mirror. The installation space for the movable device 13 in the optical writing device 600 is smaller than that for a rotary polygon mirror and the movable device 13 generates a small amount of heat; therefore, a size reduction is easy, and the optical writing device 600 is advantageous in a size reduction of the image forming apparatus.

### Object Recognition Device

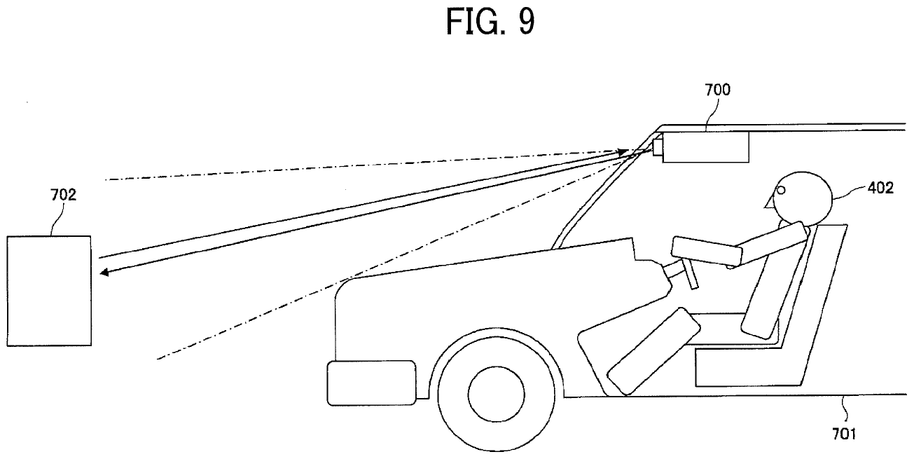

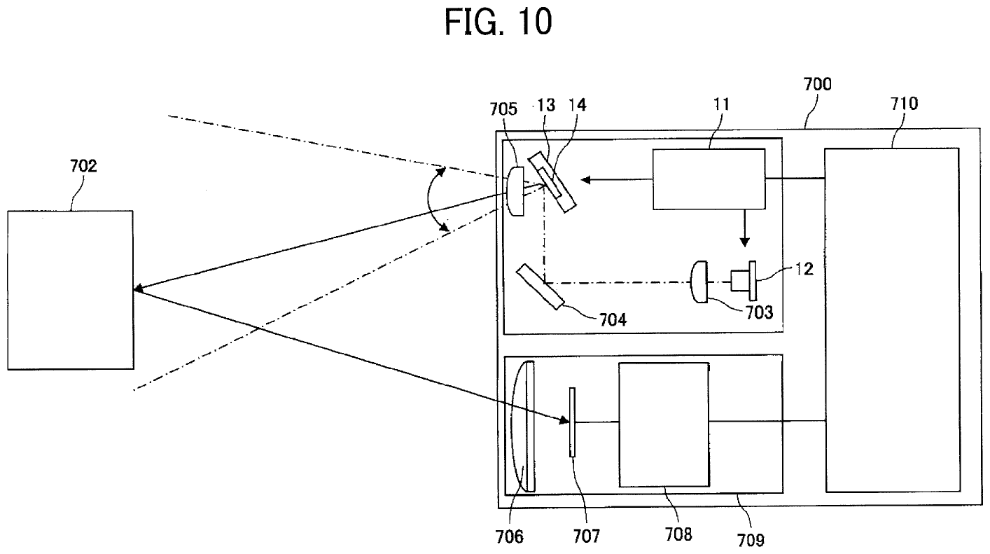

Referring to FIGS. 9 and 10, an object recognition device using the movable device 13 according to the present embodiment is described below in detail.

FIG. 9 is a schematic view illustrating an automobile 701 including a LiDAR device 700 that is an example of the object recognition device. FIG. 10 is a schematic view illustrating an example of the LiDAR device 700.

The object recognition device recognizes an object in the target direction. The object recognition device is, for example, a LiDAR device.

As illustrated in FIG. 9, the LiDAR device 700 is mounted in, for example, the automobile 701 to execute optical scanning in the target direction and receive the reflected light from a target object 702 existing in the target direction so as to recognize the target object 702.

As illustrated in FIG. 10, the laser light emitted from the light source device 12 passes through an incident optical system including a collimator lens 703, which is an optical system that converts diffuse light into substantially parallel light, and a planar mirror 704. Then, the laser light is swept by the movable device 13 including the reflective surface 14 in one or two axial directions. Then, the laser light passes through for example a projection lens 705, which is a projection optical system, to be emitted to the target object 702 in front of the apparatus. The driving of the light source device 12 and the movable device 13 is controlled by the control device 11. The light reflected by the target object 702 is optically detected by a photodetector 709. Specifically, the reflected light enters a condensing lens 706, or the like, which is an incident-light detection/reception optical system, and is received by an imaging element 707. The imaging element 707 outputs a detection signal to a signal processing circuitry 708. The signal processing circuitry 708 performs predetermined processing, such as binarization or noise processing, on the input detection signal and output the result to a distance measuring circuitry 710.

The distance measuring circuitry 710 determines the presence or absence of the target object 702 based on the difference between the timing at which the light source device 12 emits laser light and the timing at which the photodetector 709 receives the laser light or the difference in phase between the pixels of the imaging element 707 that have received the light. Furthermore, the distance measuring circuitry 710 calculates the distance information on the target object 702.

As the movable device 13 including the reflective surface 14 is less likely to be damaged as compared with a polygonal mirror and is small in size, the movable device 13 may provide a highly-durable small-sized radar device. The above-described LiDAR device is installed in, for example, a vehicle to execute optical scanning over a predetermined range so as to determine the presence or absence of an obstacle or the distance to an obstacle.

The LiDAR device may be mounted in not only a vehicle but also a movable body such as an aircraft, a ship, or a movable robot, or an immovable body such as a work robot that operates a driving target such as a manipulator without moving from the spot.

With regard to the above-described object recognition device, the LiDAR device 700 has been described as an example. However, the object recognition device is not limited to the above-described embodiment and may be any device as long as the control device 11 controls the movable device 13 including the reflective surface 14 so as to execute optical scanning and the photodetector receives the reflected light to recognize the target object 702.

The object recognition device is also applicable to, for example, the biometric authentication in which the object information, such as a shape, is calculated from the distance information obtained due to the optical scanning on a hand or a face and the record is checked to recognize the object, a security sensor that recognizes an intruder object due to the optical scanning in the target range, or a component of a three-dimensional scanner that calculates and recognizes the object information, such as a shape, from the distance information obtained due to optical scanning and output three-dimensional data.

### Laser Headlamp

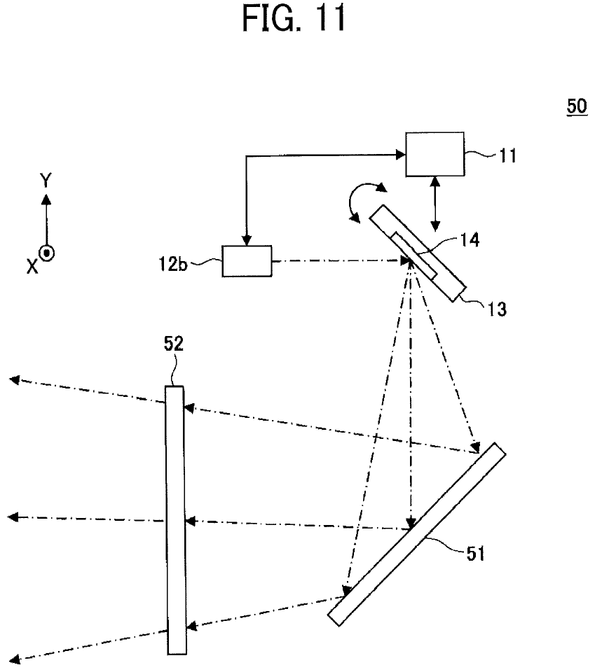

Referring to FIG. 11, a laser headlamp 50 using the movable device 13 according to the present embodiment as an automobile headlight is described. FIG. 11 is a schematic view illustrating an example of the configuration of the laser headlamp 50.

The laser headlamp 50 includes the control device 11, a light source device 12b, the movable device 13 including the reflective surface 14, a mirror 51, and a transparent plate 52.

The light source device 12b emits blue laser light. The light emitted from the light source device 12b enters the movable device 13 and is reflected by the reflective surface 14. The movable device 13 moves the reflective surface 14 in the X-direction and the Y-direction based on a signal transmitted from the control device 11 so that the blue laser light emitted from the light source device 12b is swept two-dimensionally in the X-direction and the Y-direction.

The scanning light from the movable device 13 is reflected by the mirror 51 to enter the transparent plate 52. At least one of the front surface and the back surface of the transparent plate 52 is covered with a yellow phosphor. When the blue laser light from the mirror 51 passes through the yellow phosphor coating of the transparent plate 52, the blue laser light is changed into white light in the range that is officially defined as the color of a headlight. This allows the front of the automobile to be illuminated with white light coming from the transparent plate 52.

The scanning light from the movable device 13 scatters by a predetermined degree as the scanning light passes through the phosphor of the transparent plate 52. This reduces the glare for the illumination target in front of the automobile.

When the movable device 13 is applied to the headlight of an automobile, the colors of the light source device 12b and the phosphor are not limited to blue and yellow. For example, the light source device 12b may emit near-ultraviolet radiation and the transparent plate 52 may be coated with the uniform mixture of phosphors in blue, green, and red, which are the three primary colors of light. Even in this case, the light passing through the transparent plate 52 may be converted into white light, and the front of the automobile may be illuminated with white light.

The laser headlamp 50 may be mounted in not only a vehicle but also a movable body such as an aircraft, a ship, or a movable robot, or an immovable body such as a work robot that operates a driving target such as a manipulator without moving from the spot.

### Head Mount Display

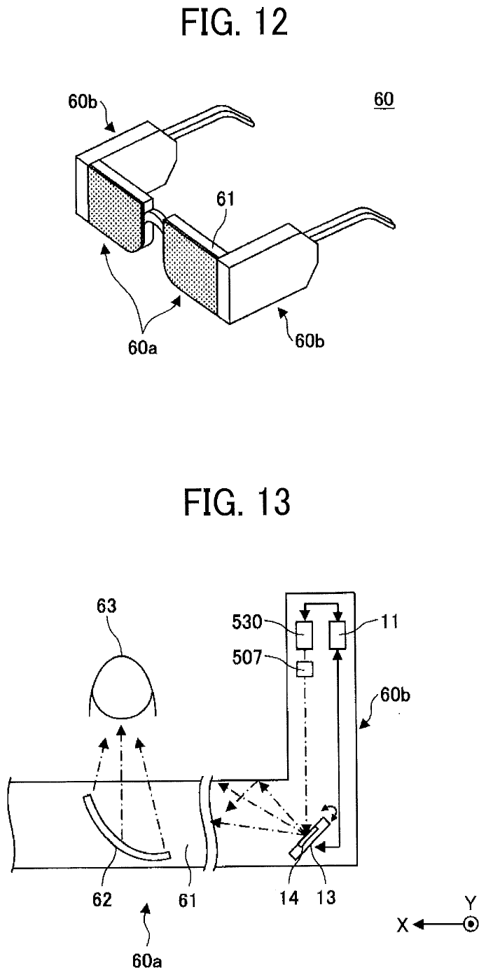

Referring to FIGS. 12 and 13, a head mount display 60 using the movable device 13 according to the present embodiment is described below. The head mount display 60 is attachable to the human head. For example, the head mount display 60 may be shaped like glasses. Hereinafter, the head mount display is abbreviated as HMD.

FIG. 12 is a perspective view illustrating an example of the external appearance of the HMD 60. As illustrated in FIG. 12, the HMD 60 includes pairs of a front 60a and a temple 60b that are substantially symmetric. The front 60a may include, for example, a light guide plate 61. An optical system, a control device, and the like, may be incorporated in the temple 60b.

FIG. 13 is a partial view illustrating an example of the configuration of the HMD 60. Although FIG. 13 illustrates the configuration for the left eye, the HMD 60 has the same configuration for the right eye.

The HMD 60 includes the control device 11, the light source unit 530, the light intensity adjuster 507, the movable device 13 including the reflective surface 14, the light guide plate 61, and a half mirror 62.

As described above, the light source unit 530 includes the laser light sources 501R, 501G, and 501B, the collimator lenses 502, 503, and 504, and the dichroic mirrors 505 and 506, which are housed as a unit in the optical housing. In the light source unit 530, the dichroic mirrors 505 and 506 combine the laser lights in the three colors from the laser light sources 501R, 501G, and 501B. The light source unit 530 emits the combined parallel light.

After the light intensity adjuster 507 adjusts the intensity of the light from the light source unit 530, the light enters the movable device 13. The movable device 13 moves the reflective surface 14 in the X-direction and Y-direction based on a signal from the control device 11 to two-dimensionally sweep the light from the light source unit 530. The driving control of the movable device 13 is performed in synchronization with the emission timings of the laser light sources 501R, 501G, and 501B so that a color image is formed with the scanning light.

The scanning light from the movable device 13 enters the light guide plate 61. The light guide plate 61 guides the scanning light to the half mirror 62 while the inner wall surface reflects the scanning light. The light guide plate 61 includes a resin, or the like, having a permeability for the wavelength of the scanning light.

The half mirror 62 reflects the light from the light guide plate 61 to the back side of the HMD 60 to emit the light toward the eyes of a wearer 63 of the HMD 60. The half mirror 62 has, for example, a free-form surface shape. The image with the scanning light is formed on the retina of the wearer 63 due to the reflection at the half mirror 62. Alternatively, the image is formed on the retina of the wearer 63 due to the reflection at the half mirror 62 and the lens effect of the crystalline lens in the eyeball. The reflection at the half mirror 62 corrects the spatial distortion of the image. The wearer 63 may observe the image formed with the light swept in the X-direction and Y-direction.

Due to the half mirror 62, the wearer 63 observes the image with the light from outside and the image with the scanning light in a superimposed manner. With a mirror instead of the half mirror 62, it is also possible to eliminate the light from outside and observe the image with the scanning light.

### Packaging

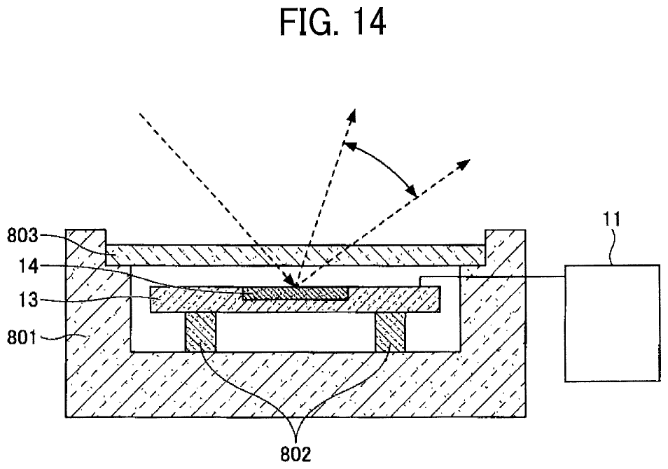

Referring to FIG. 14, the packaging of the movable device 13 according to the present embodiment is described below.

FIG. 14 is a schematic view illustrating an example of the packaged movable device 13.

As illustrated in FIG. 14, the movable device 13 is packaged such that the movable device 13 is attached to a mounting member 802 provided inside a package member 801 and part of the package member 801 is covered with a transmissive member 803 to be sealed. The inside of the package is hermetically filled with inert gas such as nitrogen. This prevents the deterioration of the movable device 13 due to oxidation and improves the durability against changes in the environment such as a temperature.

Referring to the drawings, the movable device 13 according to the present embodiment used in the optical deflection system, the optical scanning system, the image projection device, the optical writing device, the object recognition device, the laser headlamp, and the head mount display are described below in detail. In each drawing, the same component is denoted by the reference numeral, and duplicate descriptions are sometimes omitted.

In the description according to the embodiment, the optical scanning due to the rotation around a first axis is the sub-scanning, and the optical scanning due to the rotation around a second axis is the main scanning. The terms such as rotation, oscillation, and movement in the embodiment are synonymous. With regard to the directions indicated by arrows, the X-direction is parallel to the second axis, the Y-direction is parallel to the first axis, and the Z-direction is perpendicular to the XY plane. The Z-direction is an example of a “laminating direction”.

### First Embodiment

### Structure of the Movable Device

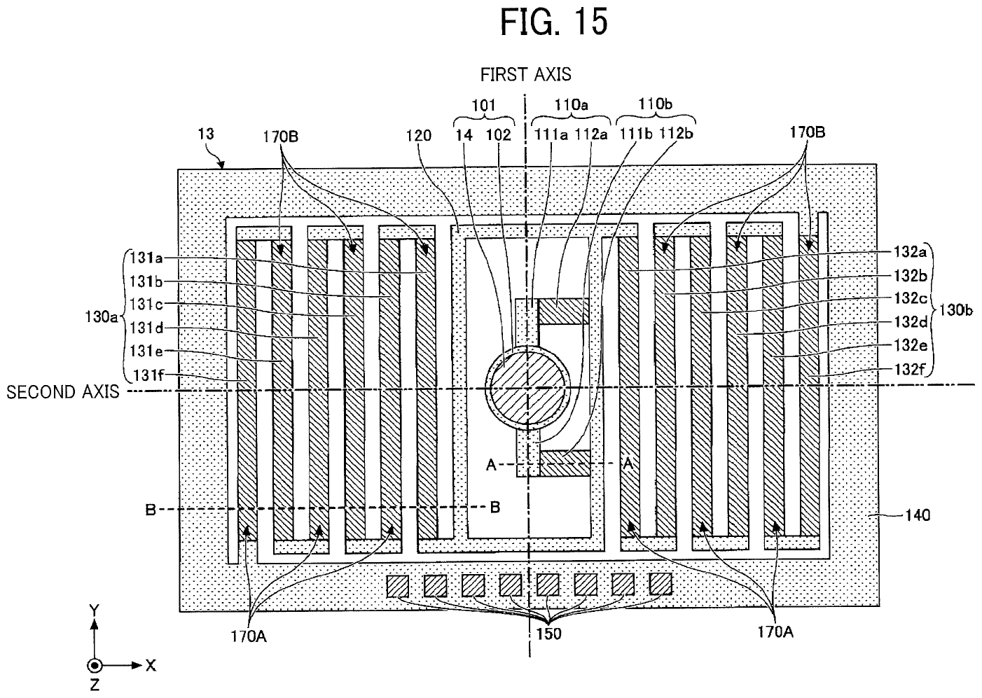

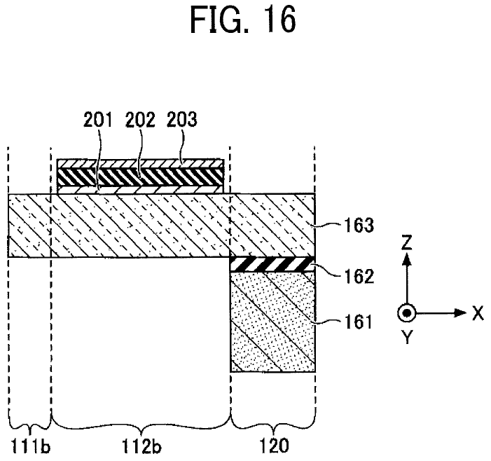

FIG. 15 is a plan view illustrating the movable device 13 according to a first embodiment of the present invention. FIG. 16 is a cross-sectional view taken through the line A-A in FIG. 15. FIG. 17 is a cross-sectional view taken through the line B-B in FIG. 15.

The movable device 13 illustrated in FIG. 15 is a cantilever optical deflection element that rotates a movable part including a reflective surface due to resonance oscillation to deflect the light incident on the reflective surface in two axial directions (around the first axis and the second axis).

The movable device 13 is configured to enable the rotation of a mirror unit 101 around the first axis corresponding to the main scanning direction and the rotation of the mirror unit 101 around the second axis corresponding to the sub-scanning direction. That is, the movable device 13 may deflect the incident light while sweeping the light in two axial directions due to the rotation of the mirror unit 101 in two axial directions. The structure of the movable device 13 is described below in detail.

The movable device 13 includes the mirror unit 101, first drives 110a and 110b, a first support 120, second drives 130a and 130b, a second support 140, and an electrode connection 150. The mirror unit 101 reflects incident light. The first drives 110a and 110b are coupled to the mirror unit 101, which is a movable part, to drive the mirror unit 101 around the first axis parallel to the Y-axis. The first support 120 supports the mirror unit 101 and the first drives 110a and 110b. The second drives 130a and 130b are coupled to the first support 120 to drive the mirror unit 101 and the first support 120 around the second axis parallel to the X-axis (perpendicular to the first axis). The second support 140 supports the second drives 130a and 130b. The electrode connection 150 is electrically connected to the first drives 110a and 110b and the second drives 130a and 130b.

For example, a single silicon on insulator (SOI) substrate is formed by etching processing, or the like, and the reflective surface 14, first piezoelectric drives 112a and 112b, second piezoelectric drives 131a to 131f and 132a to 132f, the electrode connection 150, and the like, are formed on the substrate so that various components are integrally formed in the movable device 13. Each of the above-described components may be formed after the SOI substrate is formed or while the SOI substrate is being formed.

The SOI substrate includes a silicon oxide layer 162 provided on a first silicon layer including monocrystal silicon (Si) and a second silicon layer that includes monocrystal silicon and is provided on the silicon oxide layer 162. Hereinafter, the first silicon layer is referred to as a silicon support layer 161, and the second silicon layer as a silicon active layer 163.

As the silicon active layer 163 is thin in the Z-axis direction as compared with the X-axis direction and the Y-axis direction, a member including the silicon active layer 163 functions as an elastic member having elasticity. The SOI substrate does not need to be flat and may have a curvature, etc. The member used to form the movable device 13 is not limited to the SOI substrate and may be any substrate as long as the substrate enables the integral formation by etching processing, etc., and partial elasticity.

The mirror unit 101 is a movable part including, for example, a circular mirror unit base 102 and the reflective surface 14 formed on the +Z side surface of the mirror unit base 102. The mirror unit base 102 includes, for example, the silicon active layer 163. The reflective surface 14 includes a metal thin film including, for example, aluminum, gold, or silver.

The mirror unit 101 may include a rib on the −Z side surface of the mirror unit base 102 to reinforce the mirror unit 101. The rib includes, for example, the silicon support layer 161 and the silicon oxide layer 162 to suppress the distortion of the reflective surface 14 caused due to the movement.

The first drives 110a and 110b include two torsion bars 111a and 111b and first piezoelectric drives 112a and 112b. The torsion bars 111a and 111b have one end coupled to the mirror unit base 102 and extend in the direction of the first axis to movably support the mirror unit 101. The first piezoelectric drives 112a and 112b have one end coupled to the torsion bars 111a and 111 b and have the other end coupled to the inner circumferential portion of the first support 120.

As illustrated in FIG. 16, the torsion bars 111a and 111 b include the silicon active layer 163. In the first piezoelectric drives 112a and 112b, a lower electrode 201, a piezoelectric part 202, and an upper electrode 203 are formed in this order on the +Z side surface of the silicon active layer 163 which is an elastic part. The upper electrode 203 and the lower electrode 201 include, for example, gold (Au) or platinum (Pt). The piezoelectric part 202 includes, for example, PZT (lead zirconate titanate), which is a piezoelectric material.

Returning back to FIG. 15, the first support 120 is a rectangular support that includes, for example, the silicon support layer 161, the silicon oxide layer 162, and the silicon active layer 163 so as to surround the mirror unit 101.

The second drives 130a and 130b include, for example, a plurality of second piezoelectric drives 131a to 131f and 132a to 132f that are coupled so as to be folded. One end of each of the second drives 130a and 130b is coupled to the outer circumferential portion of the first support 120, and the other end thereof is coupled to the inner circumferential portion of the second support 140.

The connection point between the second drive 130a and the first support 120 and the connection point between the second drive 130b and the first support 120 are point-symmetric with respect to the center of the reflective surface 14. Furthermore, the connection point between the second drive 130a and the second support 140 and the connection point between the second drive 130b and the second support 140 are point-symmetric with respect to the center of the reflective surface 14.

The second piezoelectric drives 131b, 131d, and 131f constitute a piezoelectric drive group 170A. The second piezoelectric drives 132a, 132c, and 132e also constitute the piezoelectric drive group 170A. The piezoelectric drive group 170A has bending and deformation in the same direction when a drive voltage is simultaneously applied to each piezoelectric part. This deformation, as a rotational force, causes the mirror unit 101 to rotate around the first axis.

The second piezoelectric drives 131a, 131c, and 131e constitute a piezoelectric drive group 170B. The second piezoelectric drives 132b, 132d, and 132f also constitute the piezoelectric drive group 170B. The piezoelectric drive group 170B has bending and deformation in the same direction when a drive voltage is simultaneously applied to each piezoelectric part. This deformation, as a rotational force, causes the mirror unit 101 to rotate around the first axis in the direction opposite to the direction due to the rotation by the piezoelectric drive group 170A.

As illustrated in FIG. 17, in the second drives 130a and 130b, the lower electrode 201, the piezoelectric part 202, and the upper electrode 203 are formed in this order on the +Z side surface of the silicon active layer 163, which is an elastic part. The upper electrode 203 and the lower electrode 201 include, for example, gold (Au) or platinum (Pt). The piezoelectric part 202 includes, for example, Pb[ZrxTi1-x]O3 0<x<1 (PZT) (lead zirconate titanate) which is a piezoelectric material.

Returning back to FIG. 15, the second support 140 is a rectangular support including, for example, the silicon support layer 161, the silicon oxide layer 162, and the silicon active layer 163 to surround the mirror unit 101, the first drives 110a and 110b, the first support 120, and the second drives 130a and 130b.

The electrode connection 150 is formed on, for example, the +Z side surface of the second support 140 to electrically connect the control device 11 to the upper electrodes 203 and the lower electrodes 201 of the first piezoelectric drives 112a and 112b and the second piezoelectric drives 131a to 131f via an electrode wire including aluminum (Al), etc. Each of the upper electrode 203 and the lower electrode 201 may be directly coupled to the electrode connection 150 or may be indirectly coupled due to, for example, the connection of the electrodes.

In the example of the case described according to the present embodiment, the piezoelectric part 202 is formed on one surface (the +Z side surface) of the silicon active layer 163 that is an elastic part. However, the piezoelectric part 202 may be provided on a different surface (e.g., the −Z side surface) of the elastic part, or the piezoelectric part 202 may be provided on both the surfaces of the elastic part.

The shape of each component is not limited to the shape according to the embodiment as long as the mirror unit 101 may be driven around at least one of the first axis and the second axis. For example, the torsion bars 111a and 11 b and the first piezoelectric drives 112a and 112b may be shaped to have a curvature.

An insulating layer including a silicon oxide layer further may be formed on at least any of the +Z side surface of the upper electrode 203 of the first drives 110a and 110b, the +Z side surface of the first support 120, the +Z side surface of the upper electrode 203 of the second drives 130a and 130b, and the +Z side surface of the second support 140.

An electrode wire is provided on the insulating layer, and the insulating layer is partially removed or no insulating layer is provided to form an opening at the connection spot where at least one of the upper electrode 203 and the lower electrode 201 is coupled to the electrode wire, whereby the design freedom of the first drives 110a and 110b, the second drives 130a and 130b, and the electrode wire may be increased, and short-circuiting due to the contact between the electrodes may be prevented. The silicon oxide layer also functions as an antireflective member.

Next, the control of the control device 11 that drives the first drives 110a and 110b and the second drives 130a and 130b of the movable device 13 is described in detail.

The application of a positive or negative voltage in a polarization direction causes the piezoelectric parts 202 included in the first drives 110a and 110b and the second drives 130a and 130b to deform (for example, expand and contract) in proportion to the potential of the applied voltage so as to produce what is called an inverse piezoelectric effect. The first drives 110a and 110b and the second drives 130a and 130b use the inverse piezoelectric effect to move the mirror unit 101.

The angle formed between the XY plane and the reflective surface 14 of the mirror unit 101 when the reflective surface 14 is tilted in the +Z direction or the −Z direction with respect to the XY plane is referred to as a deflection angle. The deflection angle in the +Z direction is referred to as a positive deflection angle, and the deflection angle in the −Z direction as a negative deflection angle.

In the first drives 110a and 110b, when a drive voltage is applied in parallel to the piezoelectric parts 202 included in the first piezoelectric drives 112a and 112b via the upper electrodes 203 and the lower electrodes 201, each of the piezoelectric parts 202 deform. The effect of the deformation of the piezoelectric part 202 causes the first piezoelectric drives 112a and 112b to be bent and deformed. Accordingly, the torsion of the two torsion bars 111a and 111b causes the driving force acting on the mirror unit 101 around the first axis so that the mirror unit 101 rotates around the first axis. The drive voltage applied to the first drives 110a and 110b is controlled by the control device 11.

Therefore, when the control device 11 causes the drive voltage having a predetermined sinusoidal waveform to be applied in parallel to the first piezoelectric drives 112a and 112b included in the first drives 110a and 110b, the mirror unit 101 may be moved around the first axis in the period of the drive voltage having a predetermined sinusoidal waveform.

In particular, for example, when the frequency of the sinusoidal voltage is set to approximately 20 kHz that is nearly equal to the resonance frequency of the torsion bars 111a and 111 b, the mirror unit 101 may resonate at approximately 20 kHz by the use of the mechanical resonance occurring due to the torsion of the torsion bars 111a and 111 b.

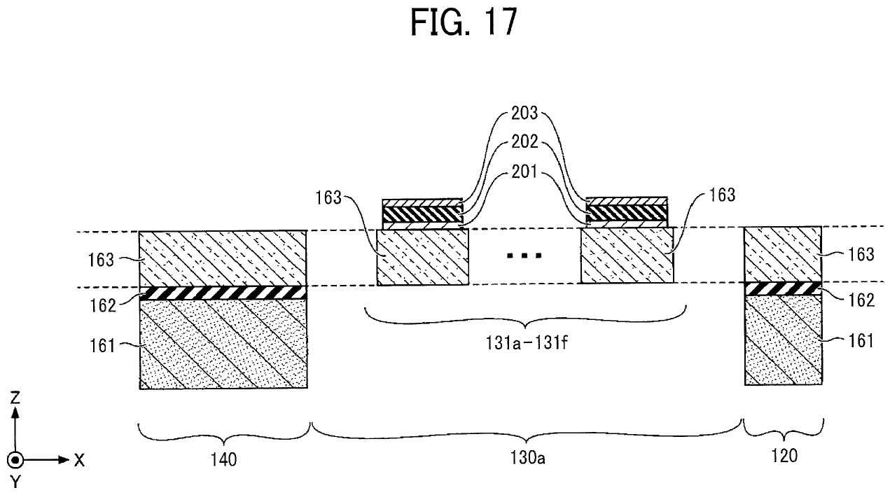

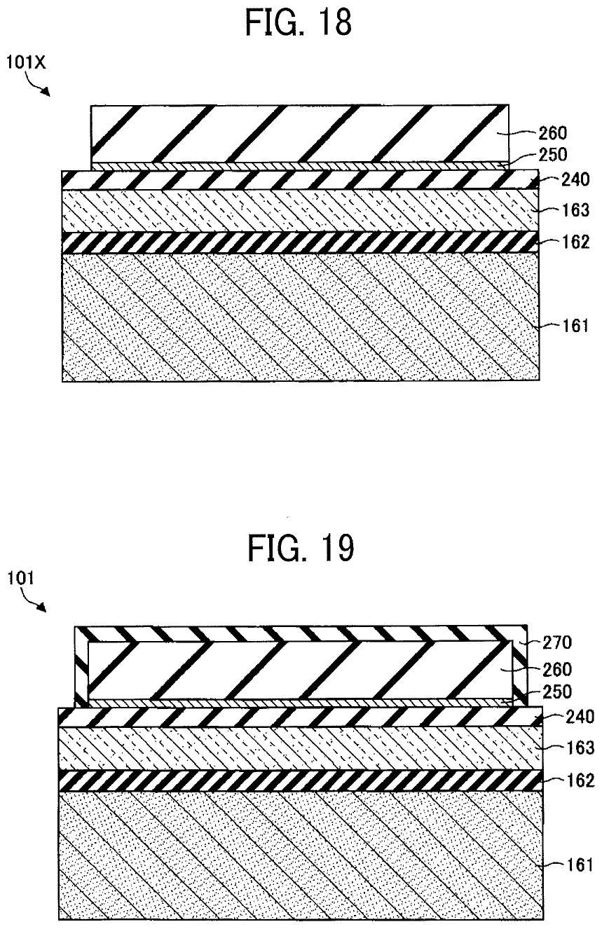

FIG. 18 is a cross-sectional view illustrating an example of the mirror unit 101 according to a comparative example. A mirror unit 101X illustrated in FIG. 18 includes the silicon support layer 161, the silicon oxide layer 162, the silicon active layer 163, an interlayer film 240, a metal film 250, and a high reflective layer 260. The material of the interlayer film 240 is, for example, SiO₂, SiN_{X}, or Al₂O₃. The material of the metal film 250 is, for example, Al, AlCu, AlSiCu, Ag, Ag alloy, or Au. The upper surface of the metal film 250 is a reflective surface that reflects light.

The high reflective layer 260 is provided so as not to lower the reflectance of the metal film 250. In this example, as the high reflective layer 260 is provided for the metal film 250 on which light is incident after passing through a protective film, the reflectance of light may be increased as compared with a case where no high reflective layer is provided. Thus, the use efficiency of light may be increased.

The high reflective layer 260 is a layer including a dielectric multi-layer film and is formed by alternately laminating a low refractive index material layer and a high refractive index material layer. Examples of the low refractive index material include SiO₂ or MgF₂. Examples of the high refractive index material include TiO₂, Nb₂O₅, ZrO₂, or Ta₂O₅. The high reflective layer 260 may include a layer including an intermediate refractive index material such as Al₂O₃. The high reflective layer 260 may be formed by using, for example, a vapor deposition method, an atomic layer deposition (ALD) method, a CVD method, or a sputtering method.

FIG. 19 is a cross-sectional view illustrating an example of the mirror unit 101 according to the first embodiment. In the mirror unit 101 illustrated in FIG. 19, a protective film 270 protects the metal film 250 and the high reflective layer 260. The mirror unit 101 according to the present embodiment includes the metal film 250, the high reflective layer 260 laminated on the upper surface of the metal film 250, and the protective film 270 that covers the metal film 250 and the high reflective layer 260.

The protective film 270 continuously covers the upper surface and the side surface of the high reflective layer 260 and the side surface of the metal film 250. As the high reflective layer 260 is formed on the upper surface of the metal film 250, the protective film 270 is not directly formed on the upper surface of the metal film 250.

That is, the mirror unit 101 is different from the mirror unit 101X according to the comparative example in that the mirror unit 101 includes the protective film 270. The protective film 270 may continuously cover the upper surface of the high reflective layer 260, the side surface of the high reflective layer 260, and the side surface of the metal film 250 so that the lower surface of the protective film 270 is in contact with the upper surface of the interlayer film 240. This is to ensure that the metal film 250 and the high reflective layer 260 are protected.

The protective film 270 may have a material to be a film that allows the passage of light entering the reflective surface of the mirror unit 101 and that is suitable for film formation by using the ALD method. Examples of such a film include an oxide film or a nitride film, which is an inorganic film. Specifically, examples of the material of the protective film 270 include Al₂O₃, Ta₂O₅, SiO₂, or SiN_{X}. A metal film or an organic film may be used as the material of the protective film 270. Selecting an oxide film or a nitride film as the material of the protective film 270 is advantageous in suppressing the deterioration of the optical characteristics. It is, in particular, advantageous as compared with a metal film or an organic film.

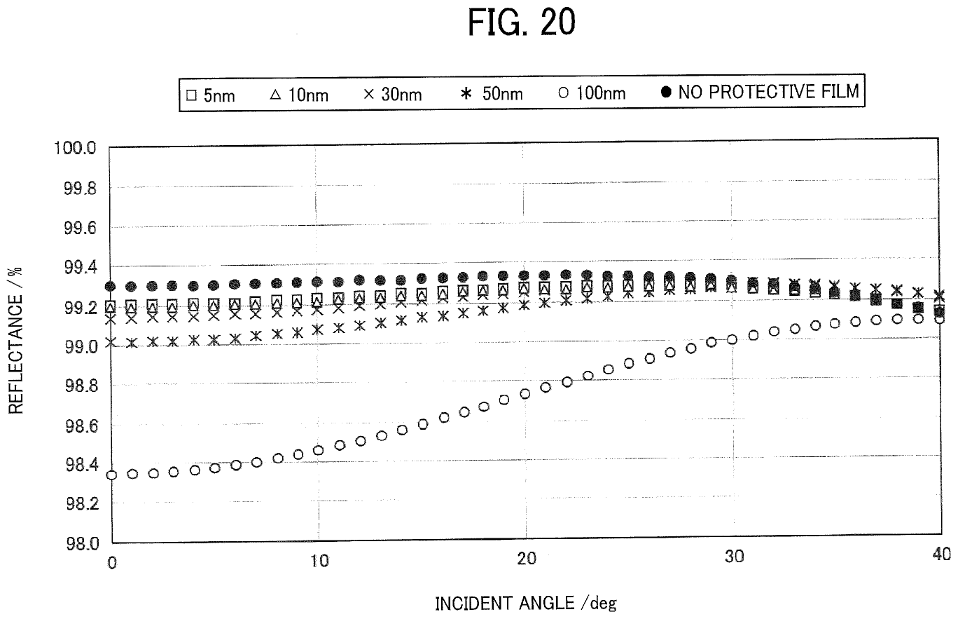

FIG. 20 is a graph illustrating a difference in the reflectance between the mirror units due to the presence or absence of a protective film. The Y-axis represents the reflectance, and the X-axis represents the incidence angle of a light beam when the incidence angle of a light bean entering the mirror unit at right angle is zero degrees. Specifically, FIG. 20 illustrates the reflectance of the mirror unit when the incident light has a wavelength λ of 905 nm and the protective film 270 having a refractive index n of 1.76 is formed as a single layer having a physical film thickness d. FIG. 20 also illustrates the reflectance of the mirror unit (the comparative example) in which the protective film 270 is not formed. Consideration is given to five types of the physical film thickness d, i.e., 5 nm, 10 nm, 30 nm, 50 nm, and 100 nm.

It is understood from FIG. 20 that, when the physical film thickness d of the protective film 270 exceeds 50 nm, the reflectance is 99% or less in the range of the incident angle from 0 degrees to 30 degrees. Therefore, the physical film thickness d of the protective film 270 may be 5 nm or more and 50 nm or less.

A decrease in the reflectance in the range of a small incident angle is a disadvantage peculiar to a mirror including a movable part. As the incident angle increases, the optical path length passing through the protective film 270 becomes longer; therefore, the apparent film thickness changes, and the dependence of the reflectance on the incident angle increases.

TABLE 1

| Physical film | Optical film | QWOT | QWOT |
|---|---|---|---|
| thickness d | thickness nd | [Reference | [Reference |
| [nm] | [nm] | wavelength 550 nm] | wavelength 905 nm] |
| 5 | 8.8 | 0.0589 | 0.0389 |
| 10 | 17.6 | 0.1178 | 0.0779 |
| 30 | 52.8 | 0.3535 | 0.2336 |
| 50 | 88.0 | 0.5891 | 0.3894 |
| 100 | 176.0 | 1.1782 | 0.7788 |

Table 1 illustrates the values of the physical film thickness d, an optical film thickness nd, and QWOT (the film thickness corresponding to ¼ of the wavelength in terms of the optical film thickness) of the protective film 270 under the conditions illustrated in FIG. 20. In Table 1, the optical film thickness nd=n (refractive index)×d (physical film thickness), and QWOT is the value of k in nd=k×λ/4.

When the physical film thickness d of the protective film 270 is increased, the optical film thickness nd is also increased by the multiplication of the refractive index. To form the high reflective layer 260, a high refractive index layer and a low refractive index layer having the film thickness of QWOT are deposited alternately so that the incident light is reflected most efficiently. As the value of QWOT of the protective film 270 approaches the value of QWOT of the high reflective layer 260, the effect on the reflectance increases.

Therefore, as illustrated in FIG. 20, as the physical film thickness increases, the reflectance in the range of the incident angle from 0 degrees to 30 degrees decreases. In this design, the reflectance of 99% is satisfied when the incident angle is 0 degrees to 40 degrees if QWOT=0.5891 or less in the case of the reference wavelength of 550 nm and if QWOT=0.3894 or less in the case of the reference wavelength of 905 nm. In this description, it is assumed that the deterioration of the optical characteristics of the protective film 270 may be suppressed when the reflectance of 99% is satisfied in the case of the incident angle of 0 degrees to 40 degrees.

That is, it is possible to suppress the deterioration of the optical characteristics of the protective film 270 when QWOT=0.5891 or less in the case of the reference wavelength of 550 nm and when QWOT=0.3894 or less in the case of the reference wavelength of 905 nm.

The method for manufacturing the movable device 13 which is an optical deflection element may include a step of forming the protective film 270 by using ALD. In other words, the protective film 270 may be formed by using the ALD. The ALD is one of the vacuum film formation techniques. According to the ALD, a thin film is formed on the deposition target surface for each atomic layer by utilizing the self-regulating characteristics of atoms.

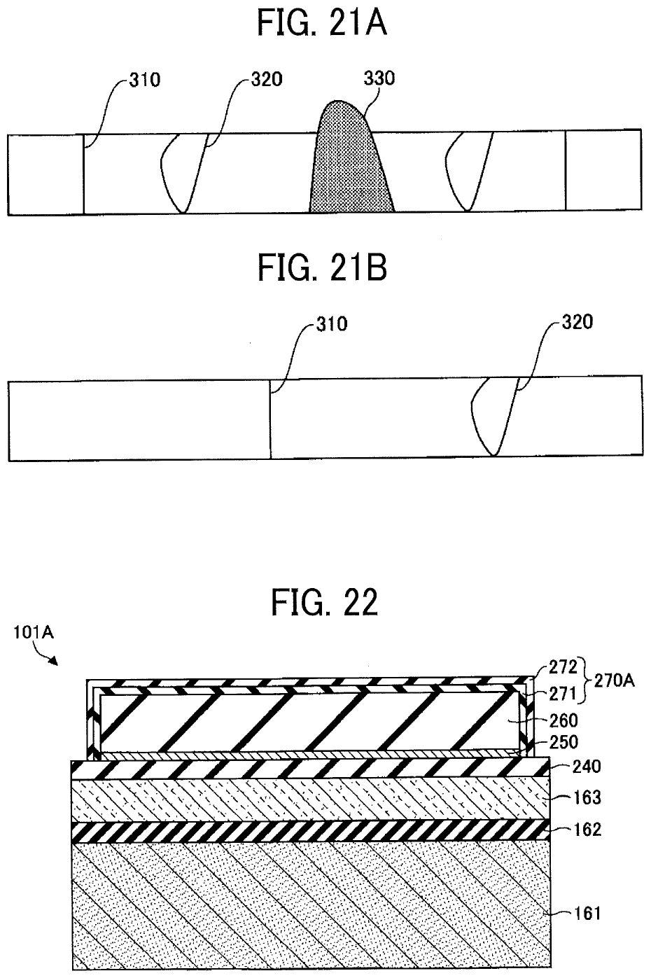

Compared with the chemical vapor deposition (CVD), which is a vapor growth method by a chemical reaction using the assist by plasma, the ALD has characteristics such as the capability to form a thin film, the capability to form a film with few defects, and the desirable coverage. Referring to FIG. 21, an explanation is given of the fact that the ALD is superior to the CVD in forming the protective film 270.

FIGS. 21A and 21B are schematic views illustrating the cross-section of the protective film. In FIGS. 21A and 21B, there are film defects, such as a crack 310, a grain boundary 320, and a particle 330. Typically, the film formation by the CVD results in many film defects as illustrated in FIG. 21A. Furthermore, as the CVD has a high film formation speed (approximately 10 to 15 nm/s), the film thickness is increased so as to affect the optical characteristics of the high reflective layer. Thus, it is difficult to form a film having a thickness of several tens of nanometers.

On the other hand, as the ALD forms a film for each atomic layer, the film formation speed is lower than that of the CVD, and therefore the occurrence of cracks and particles is less likely to occur. As illustrated in FIG. 21B, the ALD has few film defects as compared with the CVD. Furthermore, as the ALD forms a film at high temperatures, the film density in the ALD is desirable as compared with the CVD.

The film formation by the ALD has the desirable coverage as compared with the CVD. In a case where multiple layers of dissimilar materials are included (in a case where the metal film 250 and the high reflective layer 260 are covered) as in this example, seams are likely to occur on a side wall surface. Therefore, it is difficult to form a film having a thickness of several tens of nanometers by the CVD. As the ALD is a film formation using a surface reaction, the film formation by even 1 nm may theoretically result in the desirable coverage. By taking advantage of these features, it is possible to achieve both the protection of the reflective surface and the optical characteristics from the viewpoint of the reliability and the optical characteristics.

Thus, the use of the ALD allows the protective film 270, which improves the environmental resistance performance (e.g., moisture-proof performance) of the reflective surface, to be formed as a highly-dense ultrathin film (a film having a thickness of several tens of nanometers) that does not affect the optical characteristics. As a result, it is possible to achieve both the protection of the reflective surface and the prevention in the deterioration of the optical characteristics.

In order to suppress the deterioration of the optical characteristics, the protective films for the upper surface (hereinafter referred to as the upper surface) of the high reflective layer and for the side surface (hereinafter referred to as the side surface) of the high reflective layer and the metal film may have a small difference in thickness and may be uniform. A deposition method and a sputtering method have poor particle adhering performance as compared with the ALD. In the deposition method and the sputtering method, if the protective film 270 is formed to have the physical film thickness d of 5 nm or more and 50 nm or less, there is a possibility that the side surface is not sufficiently covered when the thickness of the protective film for the upper surface reaches the target thickness. To sufficiently cover the side surface, the thickness of the upper surface becomes more than the target thickness, which results in a disadvantage such as the deterioration of the optical characteristics.

For example, in the CVD, when the thickness of the protective film formed on the upper surface is 100%, the side surface formed is approximately 50 to 60%. On the other hand, in the ALD, when the thickness of the protective film formed on the upper surface is 100%, the side surface formed may be approximately 70 to 100%. Thus, the ALD is effective in solving the above disadvantages.

### Second Embodiment

In an example described according to a second embodiment of the present invention, the protective film has a two-layer structure. In the second embodiment, the descriptions of the same components as those in the above-described embodiment may be omitted.

FIG. 22 is a cross-sectional view illustrating an example of a mirror unit 101A according to the second embodiment. The mirror unit 101A illustrated in FIG. 22 is different from the mirror unit 101 (see FIG. 19) in that the protective film 270 is replaced with a protective film 270A. The protective film 270A has a two-layer structure of a first protective film 271 and a second protective film 272.

In the same manner as in the first embodiment, the metal film 250 is formed on the upper surface of the interlayer film 240, and the high reflective layer 260 is formed on the upper surface of the metal film 250. Unlike the first embodiment, the first protective film 271 is formed to continuously cover the upper surface and the side surfaces of the high reflective layer 260 and the side surface of the metal film 250, and the second protective film 272 is formed to cover the upper surface and the side surfaces of the first protective film 271.

The first protective film 271 and the second protective film 272 are formed of dissimilar materials. For example, a low refractive index material is used as the first protective film 271 and a high refractive index material is used as the second protective film 272. Alternatively, a high refractive index material may be used as the first protective film 271 and a low refractive index material may be used as the second protective film 272. Examples of the low refractive index material include SiO₂ or MgF₂. Examples of the high refractive index material include TiO₂, Nb₂O₅, ZrO₂, or Ta₂O₅.

An intermediate refractive index material such as Al₂O₃ may be used as at least one of the first protective film 271 and the second protective film 272. The above is an example, and the magnitude relationship of the refractive indexes of the first protective film 271 and the second protective film 272 are not specified as long the first protective film 271 and the second protective film 272 include dissimilar materials.

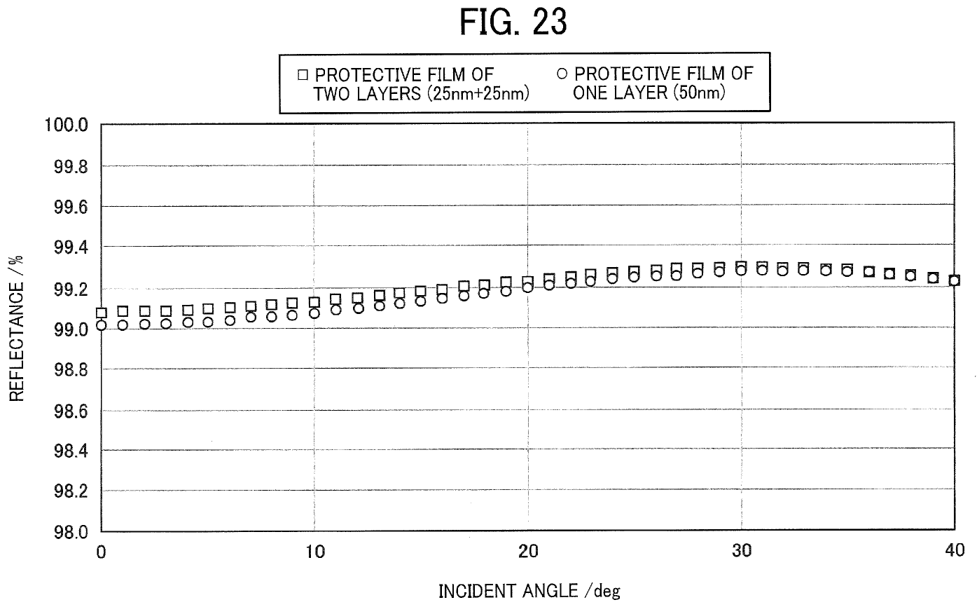

FIG. 23 is a graph illustrating the difference in the reflectance of the mirror unit depending on the number of layers in the protective film. FIG. 23 illustrates the difference in the reflectance in a case where the protective film includes two layers (the first protective film 271 is an Al₂O₃ film having a thickness of 25 nm, and the second protective film 272 is a SiO₂ film having a thickness of 25 nm) and in a case where the protective film includes a single layer (an Al₂O₃ film having a thickness of 50 nm). As illustrated FIG. 23, the protective film including two layers with an appropriate combination of dissimilar materials may improve the reflectance in the range of small incident angles (e.g., the range of incident angles of 0 degrees to 30 degrees) as compared with the protective film including a single layer.

Thus, the protective film including two separate layers may reduce the optical loss due to the protective film as understood from the tendency of the reflectance illustrated in FIG. 23 while dispersing film defects such as the above-described particles.

The above-described embodiments are illustrative and do not limit the present invention. Thus, numerous additional modifications and variations are possible in light of the above teachings. For example, elements and/or features of different illustrative embodiments may be combined with each other and/or substituted for each other within the scope of the present invention.

Any one of the above-described operations may be performed in various other ways, for example, in an order different from the one described above.

Each of the functions of the described embodiments may be implemented by one or more processing circuits or circuitry. Processing circuitry includes a programmed processor, as a processor includes circuitry. A processing circuitry also includes devices such as an application specific integrated circuitry (ASIC), digital signal processor (DSP), field programmable gate array (FPGA), and conventional circuitry components arranged to perform the recited functions.

1. An optical deflection element comprising:
a reflective surface; and
a movable part configured to rotate the reflective surface so as to deflect light incident on the reflective surface,
the movable part including:
a metal film;
a high reflective layer formed on an upper surface of the metal film; and
a protective film continuously covering an upper surface and a side surface of the high reflective layer and a side surface of the metal film.

2. The optical deflection element according to claim 1, wherein the protective film includes one of an oxide film and a nitride film that allow passage of the light.

3. The optical deflection element according to claim 1, wherein a material of the protective film includes one of Al₂O₃, Ta₂O₅, SiO₂, and SiN_{X}.

4. The optical deflection element according to claim 1, wherein the protective film has a physical film thickness of from 5 nm to 50 nm.

5. The optical deflection element according to claim 1, wherein a material of the metal film includes one of Al, AlCu, AlSiCu, Ag, Ag alloy, and Au.

6. A method for manufacturing an optical deflection element configured to rotate a movable part including a reflective surface so as to deflect light incident on the reflective surface, the movable part including a metal film and a protective film covering the metal film, and the protective film including one of an oxide film and a nitride film that allow passage of the light,
the method comprising forming the protective film by using an atomic layer deposition technique.

7. The method for manufacturing an optical deflection element according to claim 6, wherein the forming the protective film includes forming the protective film having a physical film thickness of from 5 nm to 50 nm.

8. A system comprising the optical deflection element according to claim 1.
